(19) United States
(12) Patent Application Publication
(10) Pub. No.: US 2004/0125841 A1
(43) Pub. Date: Jul. 1, 2004

(54) Surface-emitting semiconductor laser device

(75) Inventor: Tohru Takiguchi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/459,531

(22) Filed: Jun. 12, 2003

(30) Foreign Application Priority Data
Dec. 25, 2002 (JP) 2002-373865

(51) Int. Cl. H01S 5/00; H01S 3/08

(52) U.S. Cl. 372/46; 372/96

(57) ABSTRACT

A surface-emitting semiconductor laser device, having a mesa which emits a laser beam from a top surface of the mesa. The laser device includes an active layer, first and second multi-layer reflecting films, first and second electrode, and a contact layer. The first and second multi-layer reflecting films sandwich the active layer in a direction perpendicular to the surface of the active layer. The first and second electrodes sandwich the active layer in the direction perpendicular to the surface of the active layer. The contact layer extends from a side surface of the second multi-layer film to a top surface of the second multi-layer reflecting film such that the second electrode is connected to the first multi-layer film through the contact layer. The mesa includes the active layer, the second multi-layer reflecting film, and an aperture is provided on the top surface of the second multi-layer reflecting film.

### BACKGROUND OF THE INVENTION

1. Field of the Invention

The present invention relates to a surface-emitting semiconductor laser device.

2. Description of the Background Art

A surface-emitting semiconductor laser device irradiates a laser beam in a direction perpendicular to a surface thereof. For this reason, the surface-emitting semiconductor laser device can relatively freely control the size of an emitting point more than a device which irradiates a laser beam in a direction parallel to a surface thereof. For example, a mesa is formed to limit the size of an emission point to the size of the mesa or less.

In a prior art surface-emitting semiconductor laser device, a current is guided from a top electrode to an active area through a laminated electrode (Japanese Laid-open Patent Publication No. H7-507183).

In a prior art surface-emitting semiconductor laser device, a large resistance of 50 Ω or more may be generated between electrodes which sandwich an active layer thereof. The large resistance deteriorates the temperature characteristics, high-speed response, and the like of the laser device. Existence of sharp energy barrier ΔEv to holes at the hetero interface of a p-type AlAs/AlGaAs multi-layer reflecting film makes it difficult to inject the holes to increase the resistance.

### SUMMARY OF THE INVENTION

It is an object of the present invention to provide a surface-emitting semiconductor laser device in which an inter-electrode resistance is decreased.

In accordance with one aspect of the present invention, there is provided a surface-emitting semiconductor laser device, having a mesa which emits a laser beam from a top surface of the mesa. The laser device includes an active layer, first and second multi-layer reflecting films, first and second electrode, and a contact layer. The first and second multi-layer reflecting films sandwich the active layer in a direction perpendicular to the surface of the active layer. The first and second electrodes sandwich the active layer in the direction perpendicular to the surface of the active layer. The contact layer extends from a side surface of the second multi-layer film to a top surface of the second multi-layer reflecting film such that the second electrode is connected to the first multi-layer film through the contact layer. The mesa includes the active layer, the second multi-layer reflecting film, and an aperture is provided on the top surface of the second multi-layer reflecting film.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a sectional view of a surface-emitting semiconductor laser device according to a first embodiment of the present invention;

FIG. 2 is a schematic diagram of a current route of the surface-emitting semiconductor laser device according to the first embodiment of the present invention;

FIG. 3 is a schematic sectional view of a step of stacking a contact layer in a process of fabricating a surface-emitting semiconductor laser device according to the first embodiment of the present invention;

FIG. 4 is a schematic sectional view of a step of patterning a SiO₂ film as a mask;

FIG. 5 is a schematic sectional view of a step of performing etching by using a SiO₂ film as a mask to form a mesa;

FIG. 6 is a schematic sectional view of a step of forming a contact layer on a side surface of the mesa,

FIG. 7 is a schematic sectional view of a step of performing etching by using an SiO₂ as a mask to use layers up to a lower clad layer as the mesa structure;

FIG. 8 is a schematic sectional view of a step of removing SiO₂ film;

FIG. 9 is a schematic sectional view of a step of selecting oxidizing an AlAs layer to form a current blocking oxidized AlAs layer;

FIG. 10 is a schematic sectional view of a step of patterning an SiO₂ insulating layer;

FIG. 11 is a schematic sectional view of a step of opening the top surface of the mesa by etching;

FIG. 12 is a schematic sectional view of a step of removing an SiO₂ film

FIG. 13 is a schematic sectional view of a step of patterning an SiO₂ insulating film;

FIG. 14 is a schematic sectional view of a step of forming a P-type electrode at the peripheral portion of the top of the mesa; and

FIG. 15 is a schematic sectional view of a step of forming an N-type electrode.

### DETAILED DESCRIPTION OF PREFERRED EMBODIMENTS

Surface-emitting semiconductor laser devices according to embodiments of the present invention will be described below with reference to the accompanying drawings. The same reference numerals as in the drawings denote the same parts in the drawings.

### First Embodiment

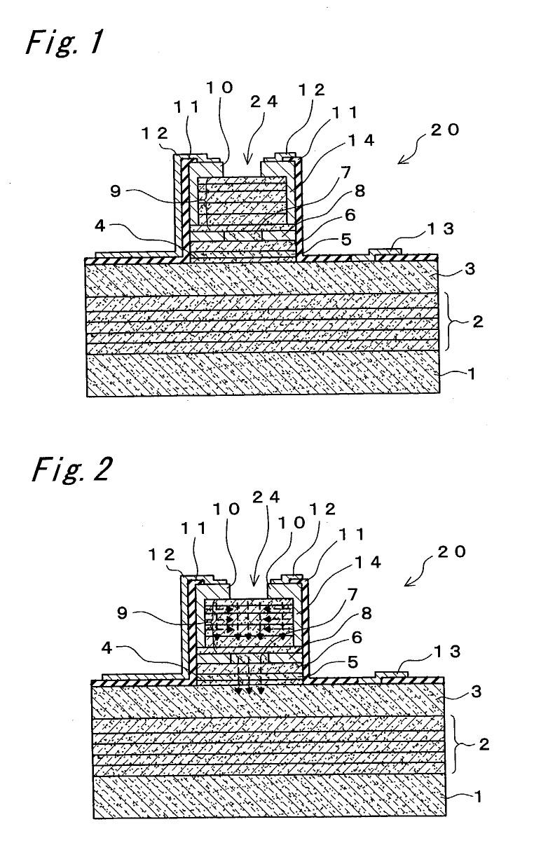

A surface-emitting semiconductor laser device according to the first embodiment of the present invention will be described below with reference to FIGS. 1 and 2. FIG. 1 shows a sectional structure of a surface-emitting semiconductor laser device 20, and FIG. 2 shows current flow paths extending from a second electrode 12 to an active layer 5 through contact layers 10 and 14 and current blocking layers 7 and 8. This surface-emitting semiconductor laser device 20 has a mesa 16 to emit a laser beam vertically upward from an opening 24 of the top plane of the mesa. The surface-emitting semiconductor laser device 20 includes the active layer 5 and a vertical resonator constituted by first and second multi-layer reflecting films 2 and 9 which vertically sandwich the active layer 5. The mesa includes the active layer 5, the current blocking layers 7 and 8, and the second multi-layer reflecting film 9. Furthermore, the contact layers 10 and 14 which connect the second multi-layer reflecting film 9 and the second electrode 12 to each other are formed in an area extending from the top of the second multi-layer reflecting film 9 to the side surface. For this reason, the current flow paths extending from the contact layers 10 and 14 to the second multi-layer reflecting film 9, the current flow path is expanded to flow a current parallel to the surface of the second multi-layer reflecting film 9 is formed, and the current flow path which causes a current to traverse a hetero interface of the second multi-layer reflecting film 9 is reduced. In this manner, an electric resistance between the electrode 12.and an electrode 13 can be suppressed from being increased.

The further detailed sectional structure of the surface-emitting semiconductor laser device 20 will be described below with reference to FIG. 1 in a direction perpendicular to the surface of the structure. That is, the layers of the structure will be sequentially described by using the N-type GaAs substrate 1 as a starter. In the surface-emitting semiconductor laser device 20, an N-type AlAs/AlGaAs multi-layer reflecting film 2 serving as a first multi-layer reflecting film and an N-type GaAs layer 3 are sequentially stacked on the N-type GaAS substrate 1. A mesa is formed on the top of the resultant structure. The mesa includes an N-type AlGaAs clad layer 4, an AlGaAs/GaAs quantum well active layer 5, a P-type AlGaAs clad layer 6, a current blocking layer constituted by a P-type AlAs layer 7 (having a thickness of 30 nm) and an oxidized AlAs layer 8, and a P-type AlAs/AlGaAs multi-layer reflecting film 9 serving as a second multi-layer reflecting film. In addition, P-type GaAs contact layers 10 and 14 are formed to cover a peripheral portion of the top and the side surface of the P-type AlAs/AlGaAs multi-layer reflecting film 9. The side surfaces of the P-type GaAs contact layers 10 and 14 are covered with an SiO₂ insulating film 11 to form a P-type electrode 12 constituted by a AuZn alloy film connected to the contact layer 10 at the peripheral portion of the top of the mesa. An N-type electrode 13 constituted by an AuGe alloy film connected to the N-type GaAs layer 3 is formed through an opening formed in the SiO₂ insulating film 11 at a position which is slightly spaced apart from the mesa.

Furthermore, a current flow path extending from the two electrodes 12 and 13 will be described below with reference to FIG. 2. A current flows from the P-type electrode 12 into the multi-layer reflecting film 9 through the P-type contact layers 10 and 14. At this time, since the P-type contact layers 10 and 14 are formed not only on the top of the second multi-layer reflecting film 9 but also on the side surface, the current flows parallel to the surface of the multi-layer reflecting film 9 to make it possible to reduce the number of current paths which traverse the hetero interface. In this manner, the electric resistance can be suppressed from being increased. The current flows in the current blocking AlAs layer 7 and flows into the active layer 5. Thereafter, the current flows into the N-type electrode 13 through the N-type GaAs layer 3.

As the N-type AlAs/AlGaAs multi-layer reflecting film 2 serving as the first multi-layer reflecting film, 40 pairs of AlAs layers each having a thickness of 74 nm and AlGaAs layers each having a thickness of 63 nm are stacked. The carrier concentration of the N-type AlAs/AlGaAs multi-layer reflecting film 2 is 1×10¹⁸ cm⁻³. As the P-type AlAs/AlGaAs multi-layer reflecting film 9 serving as the second multi-layer reflecting film, 18 pairs of AlAs layers each having a thickness of 74 nm and a carrier concentration P=3×10¹⁸ cm⁻³ and AlGaAs layers each having a thickness of 63 nm and a carrier concentration P of 1×10¹⁸ cm⁻³ are stacked.

A process of fabricating a surface-emitting semiconductor laser device will be described below.

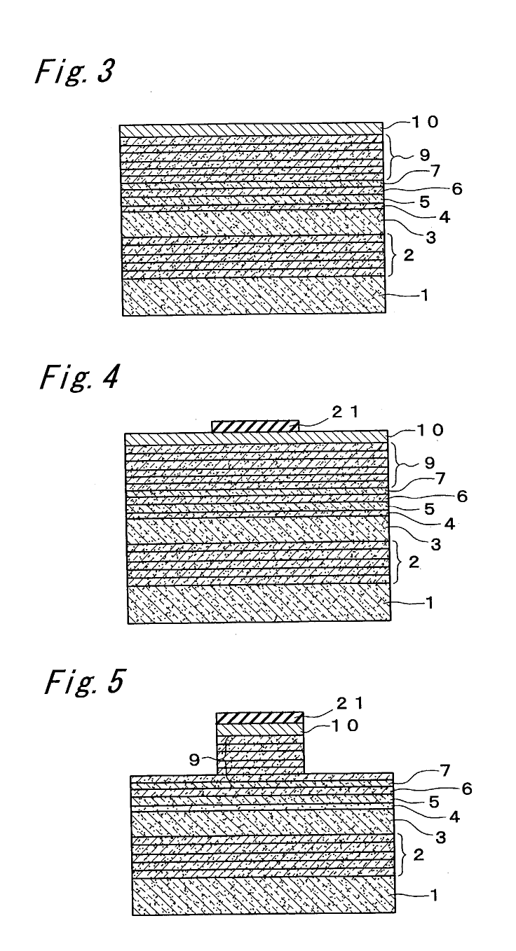

(a) On the N-type GaAS substrate 1, by the metal organic chemical vapor deposition (hereinafter referred to as MOCVD) method, the N-type AlAs/AlGaAs multi-layer reflecting film 2, the N-type GaAs layer 3, the N-type AlGaAs clad layer 4, the AlGaAs/GaAs quantum well active layer 5, the P-type AlGaAs clad layer 6, the P-type AlAs layer 7 the P-type AlAs/AlGaAs multi-layer reflecting film 9, and the P-type GaAs contact layer 10 are sequentially stacked and grown (FIG. 3).

(b) An SiO₂ insulating film 21 is formed on the P-type GaAs contact layer 10 and patterned to leave a mesa forming part (FIG. 4).

(c) By dry etching such as a Reactive Ion Beam Etching (hereinafter referred to as RIBE), the lower P-type GaAs contact layer 10 which is not covered with the SiO₂ insulating film 21 is completely etched by using the patterned SiO₂ insulating film 21 as a mask, and etching is performed until the P-type AlAs/AlGaAs multi-layer reflecting film 9 is partially etched. In this manner, the masked portion forms a mesa (FIG. 5).

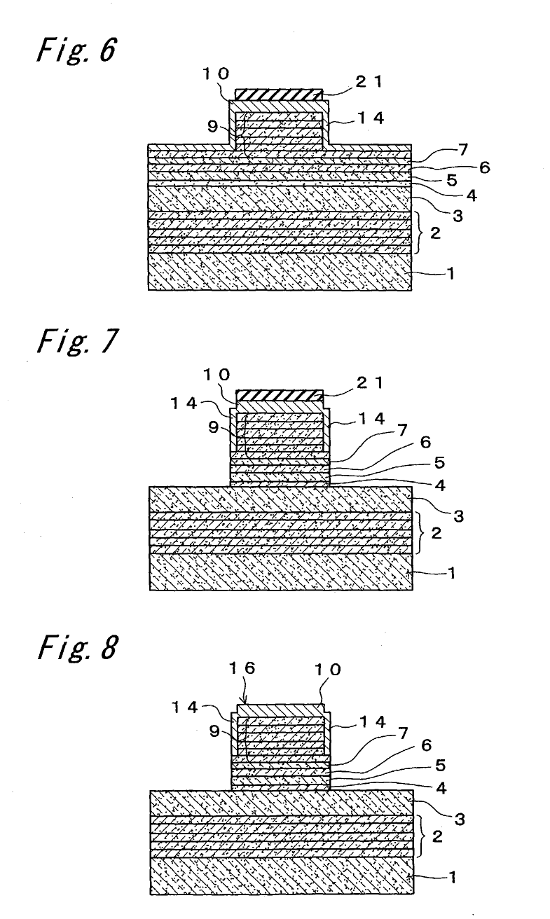

(d) By the MOCVD method, the P-type GaAs contact layer 14 is stacked and grown on the side surface of the mesa and a portion which is not covered with the SiO₂ insulating film 21 (FIG. 6). In this case, when the wafer is exposed to the air to oxidize the layers containing Al, it is difficult to grow crystal on the oxidized surface. The wafer can be preferably conveyed between a dry etching device and an MOCVD device without being exposed to the air. In addition, it is preferable that the dry etching step and the crystal growing step by the MOCVD method can be performed.

(e) By dry etching such as RIBE method, The P-type AlAs/AlGaAs multi-layer reflecting film 9, the P-type AlAs layer 7, the P-type AlGaAs clad layer 6, the AlGaAs/GaAs quantum well active layer 5, and the N-type AlGaAs clad layer 4 are etched by using the SiO₂ insulating film 21 as a mask (FIG. 7).

(f) The SiO₂ insulating film 21 is removed by etching (FIG. 8).

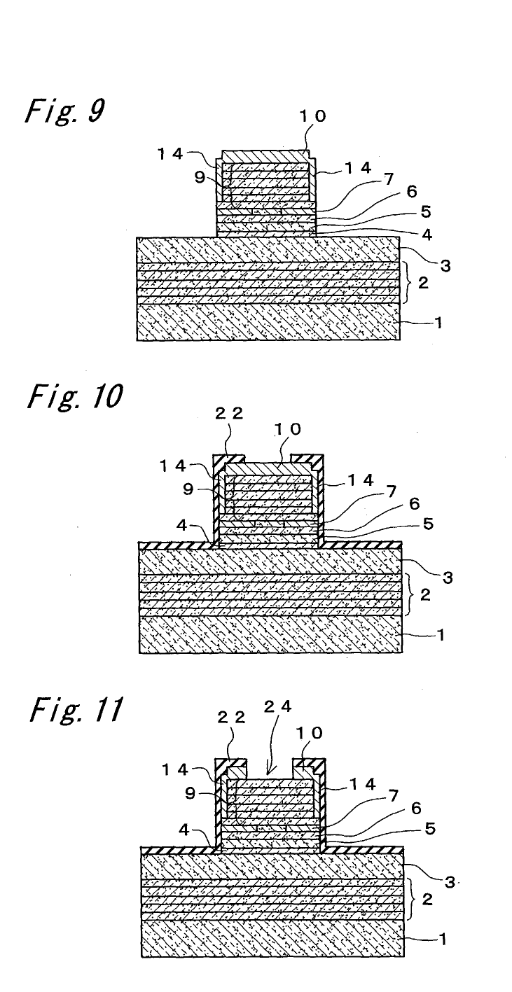

(g) The wafer is heated to 400° C. or higher in steam having a temperature of 80° C. and bubbled by nitrogen. In this manner, the P-type AlAs layer 7 is selectively oxidized to form the oxidized AlAs layer 8 (FIG. 9). For example, the process is performed for about 10 minutes to a mesa having a diameter of 30 μm to leave an unoxidized AlAs layer 7 having a central portion having a diameter of 15 μm, thereby forming the oxidized AlAs layer 8 on the peripheral portion. Since the oxidized AlAs layer 8 has a large resistance, the current is blocked by the AlAs layer 7 formed at the center. The AlAs layer 7 serves as a current path. For this reason, the AlAs layer 7 formed at the center and the oxidized AlAs layer 8 formed on the peripheral portion are called a current blocking layer. The radial thickness of the oxidized AlAs layer 8 makes it possible to limit the current path to a predetermined diameter. As a result, the diameter of laser emission can be controlled.

(h) When an SiO₂ insulating layer 22 is formed and then patterned to remove the SiO₂ insulating layer 22 at the top of the mesa (FIG. 10).

(i) The P-type GaAs contact layer 10 formed at the top of the mesa is removed by etching by using the SiO₂ insulating layer 22 as a mask to form an opening 24 for emitting a laser beam (FIG. 1 1).

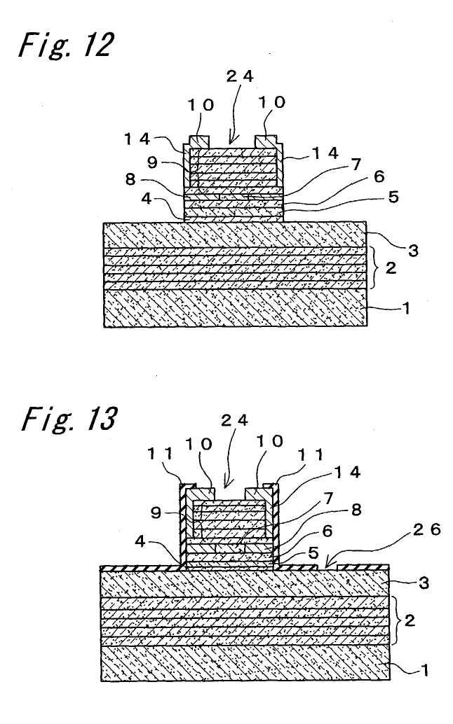

(j) The SiO₂ insulating film 21 serving as a mask is removed by etching (FIG. 12).

(k) The SiO₂ insulating film 11 is formed and then patterned to remove the SiO₂ insulating film 11 at the top of the mesa 16. The SiO₂ insulating film 11 is removed at a position which is slightly spaced apart from the mesa 16 to expose the N-type GaAs layer 3, thereby forming an opening 26 for the N-type electrode 13 (FIG. 13).

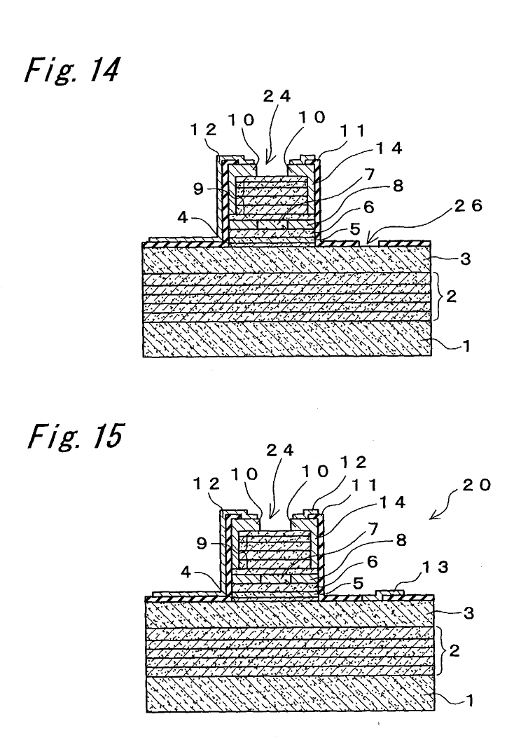

(l) The P-type electrode 12 for connecting the contact layers 10 and 14 to each other is formed on the peripheral portion of the top of the mesa 16 (FIG. 14).

(m) The N-type electrode 13 for connecting the N-type GaAs layer 3 to the opening 26 is formed (FIG. 15).

With the above steps, the surface-emitting semiconductor laser device 20 is fabricated.

According to the surface-emitting semiconductor laser device of the embodiments, a-contact layer for electrically connecting an electrode to a first multi-layer reflecting film is formed in an area extending from the top of the first multi-layer film constituting a mesa to the side surface. In this manner, since a current flows from the contact layer through a current path parallel to the layer of the multi-layer reflecting film, an increase in resistance caused by the current passing through a hetero interface can be reduced.

Although the present invention has been described in connection with the preferred embodiments thereof with reference to the accompanying drawings, it is to be noted that various changes and modifications are apparent to those skilled in the art. Such changes and modifications are to be understood as included within the scope of the present invention as defined by the appended claims, unless they depart therefrom.

What is claimed is:

1. A surface-emitting semiconductor laser device, having a mesa which emits a laser beam from a top surface of the mesa, comprising:
an active layer;
first and second multi-layer reflecting films which sandwich the active layer in a direction perpendicular to the surface of the active layer;
first and second electrodes which sandwich the active layer in the direction perpendicular to the surface of the active layer; and
a contact layer extending from a side surface of the second multi-layer film to a top surface of the second multi-layer reflecting film such that the second electrode is connected to the second multi-layer film through the contact layer,
wherein the mesa includes the active layer, the second multi-layer reflecting film, and an aperture is provided on the top surface of the second multi-layer reflecting film.

2. A surface-emitting semiconductor laser device, having a mesa which emits a laser beam from the top plane of the mesa, comprising:
an active layer;
first and second multi-layer reflecting layers which sandwich the active layer in a direction perpendicular to a surface of the active layer;
a current blocking layer provided between the active layer and the second multi-layer reflecting layer and in which electric resistivity of a central part of the current blocking layer is lower than that of a peripheral part enclosing the central part;
a contact layer formed in an area extending from a side surface of the second multi-layer reflecting film to a top plane of the second multi-layer reflecting film;
a first electrode provided between the first multi-layer reflecting film and the active layer; and
a second electrode provided on the top surface of the mesa and connected to the active layer through the contact layer and the second multi-layer reflecting film.
